(19) United States
(12) Patent Application Publication
(10) Pub. No.: US 2013/0126875 A1
(43) Pub. Date: May 23, 2013

(54) LIQUID CRYSTAL DISPLAY DEVICE

(71) Applicant: JAPAN DISPLAY EAST INC., Mobara-shi (JP)

(72) Inventors: Tomokazu ISHIKAWA, Mobara (JP); Masato SHIMURA, Mobara (JP); Takamitsu KAMADA, Hitachinaka (JP)

(73) Assignee: JAPAN DISPLAY EAST INC., Mobara-shi (JP)

(21) Appl. No.: 13/677,344

(22) Filed: Nov. 15, 2012

(30) Foreign Application Priority Data
Nov. 21, 2011 (JP) 2011-253597

(51) Int. Cl. H01L 33/00

(52) U.S. Cl. CPC H01L 33/0041
USPC 257/59

(57) ABSTRACT

The liquid crystal display device includes a TFT substrate on which TFT patterns each having a scanning signal line, a data signal line, and a pixel electrode are formed, a color filter substrate arranged to face the TFT substrate, and columnar spacers formed on a surface of the color filter substrate facing the TFT substrate, in which at least a part of the TFT patterns includes a seat that is formed over the scanning signal line or below the pixel electrode, and directly or indirectly supports one of the columnar spacers, and in which an area in which the seat provided in the TFT pattern formed in a center portion of the TFT substrate supports the columnar spacer is larger than an area in which the seat provided in the TFT pattern formed outside of the center portion of the TFT substrate supports the columnar spacer.

### CROSS-REFERENCE TO RELATED APPLICATION

The present application claims priority from Japanese application JP2011-253597 filed on Nov. 21, 2011, the content of which is hereby incorporated by reference into this application.

### BACKGROUND OF THE INVENTION

1. Field of the Invention

The present invention relates to a liquid crystal display device.

2. Description of the Related Art

In a liquid crystal panel, a seal material is interposed between a TFT substrate and a color filter substrate, and liquid crystal is sealed into a space surrounded by the TFT substrate, the color filter substrate, and the seal material to configure a liquid crystal layer. In this configuration, as disclosed in JP 2002-350861 A, columnar spaces are provided on the color filter substrate for the purpose of controlling a thickness of the liquid crystal layer with high precision.

### SUMMARY OF THE INVENTION

When the liquid crystal panel and a front window are hybridized (adhered with a UV resin), a stronger stress is exerted on a center portion of the liquid crystal panel than a peripheral portion thereof. As a result, even if a distance between a TFT substrate 220 and a color filter substrate 230 is uniformed in a plane before the liquid crystal panel and the front window are hybridized as illustrated in FIG. 11-(A), a distance in the center portion between both the substrates maybe narrower than a distance in an outer portion after the liquid crystal panel and the front window are hybridized as illustrated in FIG. 11-(B). Thus, the liquid crystal panel strains after the liquid crystal panel and the front window are hybridized with the result that a phenomenon that yellow unevenness occurs in a peripheral portion of the liquid crystal panel, which is so-called “yellow border” may occur.

The present invention has been made in view of the above problem, and therefore an object of the present invention is to provide a liquid crystal display device that can prevent color unevenness from occurring in the peripheral portion of the liquid crystal panel after the front window has adhered to the liquid crystal panel.

The summary of the typical features in the invention disclosed in the present application will be described below in brief.
(1) According to the present invention, there is provided a liquid crystal display device including: a TFT substrate on which a plurality of TFT patterns each having a scanning signal line, a data signal line, and a pixel electrode are formed; a color filter substrate which is arranged to face the TFT substrate; and a plurality of columnar spacers which are formed on a surface of the color filter substrate facing the TFT substrate, wherein at least a part of the plurality of TFT patterns includes a seat that is formed over the scanning signal line or below the pixel electrode, and directly or indirectly supports one of the plurality of columnar spacers, and wherein an area in which the seat provided in the TFT pattern formed in a center portion of the TFT substrate supports the columnar spacer is larger than an area in which the seat provided in the TFT pattern formed outside of the center portion of the TFT substrate supports the columnar spacer.
(2) In the liquid crystal display device according to the item (1), the area in which the seat provided in the TFT pattern formed in the TFT substrate supports the columnar spacer may be smaller outward from the center portion of the TFT substrate.
(3) In the liquid crystal display device according to the item (2), the seat provided in the TFT pattern formed in the center portion of the TFT substrate may support an entire end surface of the columnar spacer, the seat provided in the TFT pattern formed between the center portion and a peripheral portion of the TFT substrate may support a partial end surface of the columnar spacer, and no seat may be provided in the TFT pattern formed in the peripheral portion of the TFT substrate.
(4) In the liquid crystal display device according to the item (1), when the seat is formed over the scanning signal line, the seat may be made of the same material as that of the pixel electrode, and formed in the same layer as that of the pixel electrode, and when the seat is formed below the pixel electrode, the seat may be made of the same material as that of the scanning signal line, and formed in the same layer as that of the scanning signal line.
(5) In the liquid crystal display device according to the item (1), heights of the seats provided in the plurality of TFT patterns may be identical with each other.
(6) In the liquid crystal display device according to the item (1), the plurality of columnar spacers may have the same shape, and the plurality of columnar spacers may be arranged on the color film substrate at predetermined intervals.

According to an aspect of the present invention, a drag caused by the columnar spacer in the center portion of the liquid crystal panel is larger than that in the peripheral portion thereof, thereby being capable of preventing color unevenness from occurring in the peripheral portion of the liquid crystal panel after the front window adheres to the liquid crystal panel.

### BRIEF DESCRIPTION OF THE DRAWINGS

FIG. 1 is a schematic view illustrating a liquid crystal display device according to an embodiment of the present invention;

FIG. 2 is a diagram illustrating a liquid crystal panel; FIG. 3 is a diagram illustrating a basic configuration of a

TFT pattern;

FIG. 4 is a diagram illustrating a relationship of a plurality of areas defined in a TFT substrate;

FIG. 5A is a diagram illustrating a configuration of the TFT pattern formed in an area A;

FIG. 5B is a diagram illustrating a configuration of the TFT pattern formed in an area B;

FIG. 6A is a diagram illustrating a relationship between a columnar spacer and a seat in the area A;

FIG. 6B is a diagram illustrating a relationship between the columnar spacer and the seat in the area B;

FIG. 6C is a diagram illustrating a relationship between the columnar spacer and the seat in the area C;

FIG. 7 is a diagram illustrating a relationship of a distance between the TFT substrate and a color filter substrate before the liquid crystal panel and the front window are hybridized;

FIG. 8A is a diagram illustrating a configuration of the TFT pattern formed in the area A;

FIG. 8B is a diagram illustrating a configuration of the TFT pattern formed in the area B;

FIG. 9A is a diagram illustrating a relationship between the columnar spacer and the seat in the area A;

FIG. 9B is a diagram illustrating a relationship between the columnar spacer and the seat in the area B;

FIG. 9C is a diagram illustrating a relationship between the columnar spacer and the seat in the area C;

FIG. 10A is a diagram illustrating one example of a relationship between a position of the liquid crystal panel in a cross-section and a contact area between the seat and the columnar spacer;

FIG. 10B is a diagram illustrating another example of the relationship between the position of the liquid crystal panel in the cross-section and the contact area between the seat and the columnar spacer;

FIG. 10C is a diagram illustrating still another example of the relationship between the position of the liquid crystal panel in the cross-section and the contact area between the seat and the columnar spacer; and

FIG. 11 is a diagram illustrating a relationship of the distance between the TFT substrate and the color filter substrate before the liquid crystal panel and the front window are hybridized in a related art.

### DETAILED DESCRIPTION OF THE INVENTION

Hereinafter, embodiments of the present invention will be described with reference to the accompanying drawings.

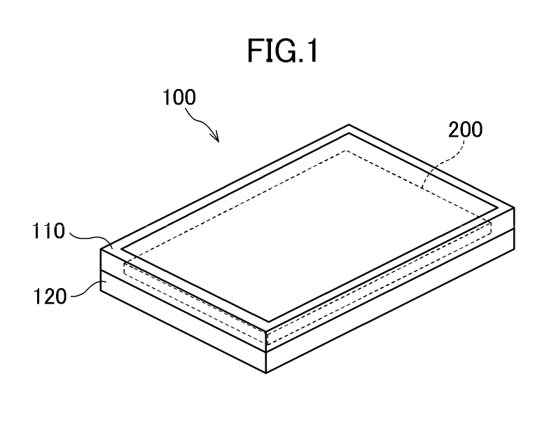

FIG. 1 schematically illustrates a liquid crystal display device 100 according to an embodiment of the present invention. As illustrated in FIG. 1, the liquid crystal display device 100 includes a liquid crystal panel 200 fixedly interposed between an upper frame 110 and a lower frame 120, and a backlight device not shown and the like.

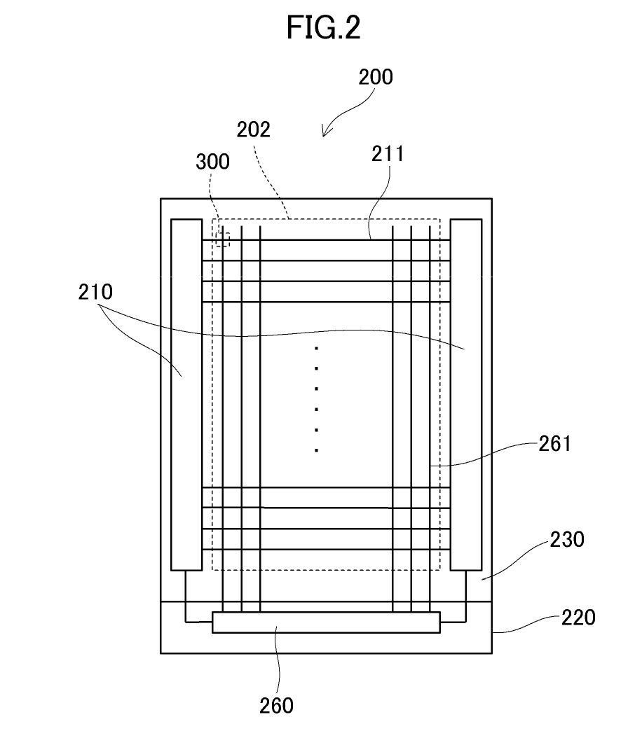

FIG. 2 illustrates a configuration of the liquid crystal panel 200 in FIG. 1. The liquid crystal panel 200 includes two substrates of a TFT (thin film transistor) substrate 220 and a color filter substrate 230, and a liquid crystal composition is sealed between those substrates. The TFT substrate 220 includes in order scanning signal line driver circuits 210 that apply a given voltage to scanning signal lines 211 in sequence, and a driver circuit 260 that controls the scanning signal line driver circuits 210, and applies a voltage corresponding to a tone value of each pixel to a plurality of data signal lines 261 extending to intersect perpendicularly with the scanning signal lines 211 in a pixel area 202.

On the TFT substrate 220 are formed TFT patterns 300 each corresponding to a pair of one scanning signal line 211 and one data signal line 261. For simplification of description, only one TFT pattern 300 is illustrated in FIG. 2.

FIG. 3 illustrates a basic configuration of each TFT pattern 300. As illustrated in FIG. 3, the TFT pattern 300 includes a semiconductor area 302 made of amorphous silicon (a-Si), a gate line 211 (GAL) functioning as each scanning signal line, a drain line 261 (DCR) functioning as each data signal line, and a source electrode 304 (DCR) functioning as each pixel electrode. Further, in this embodiment, seats that each support a columnar spacer disposed on the facing color filter substrate 230 are formed over the scanning signal line (gate line 211) or below the pixel electrode (source electrode 304) on at least one or several of the TFT patterns 300 formed on the TFT substrate 220. Hereinafter, a description will be given of a configuration example of the seat provided in each of the TFT patterns 300 according to a position on the TFT substrate 220.

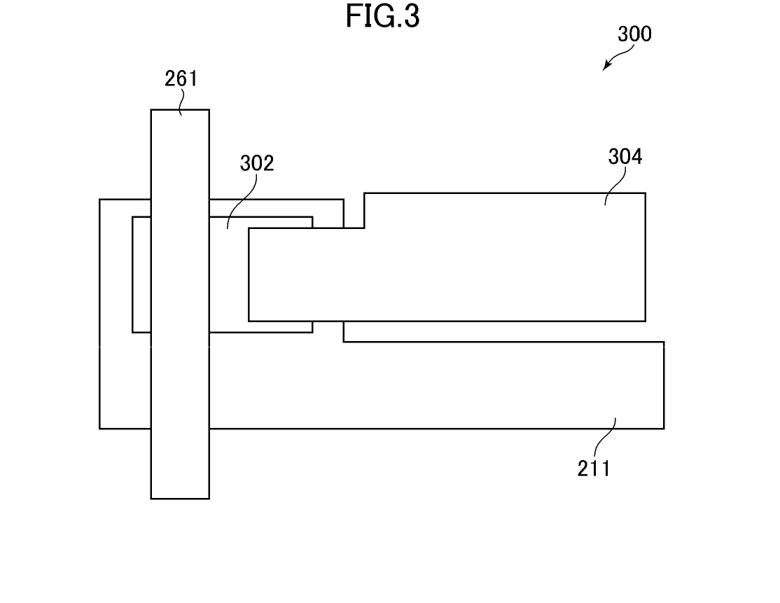

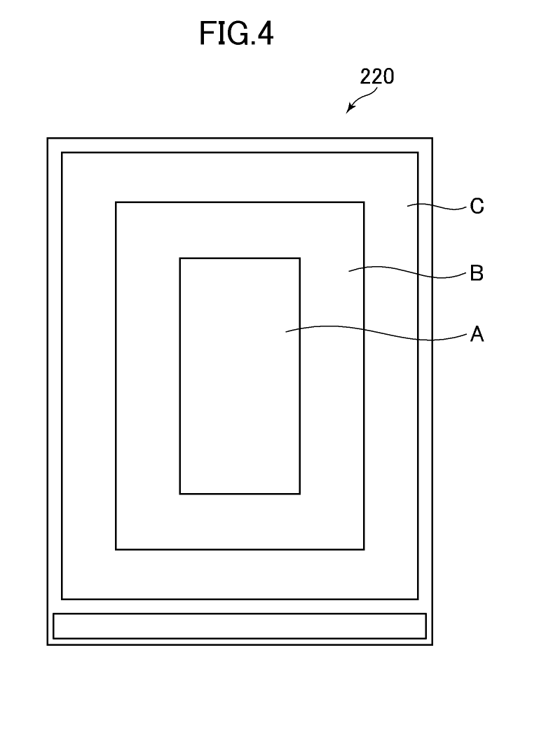

FIG. 4 illustrates a relationship among a plurality of areas defined in the TFT substrate 220. In an example illustrated in FIG. 4, three areas of an area A, an area B, and an area C are defined in the TFT substrate 220. The area A is confined to an area of a center portion including a center of the TFT substrate 220, and the area B is confined to an area between the area A and the area C of a peripheral portion. The area C is confined to an area of the peripheral portion in the pixel area 202 of the TFT substrate 220. In this embodiment, though an example is described in which the pixel area 202 of the TFT substrate 220 is divided into three areas, an area expanding from the center portion to the peripheral portion may be divided into a plurality of areas other than three.

### First Embodiment

Hereinafter, a description will be given of an example (first embodiment) in which the seat is formed over the scanning signal line.

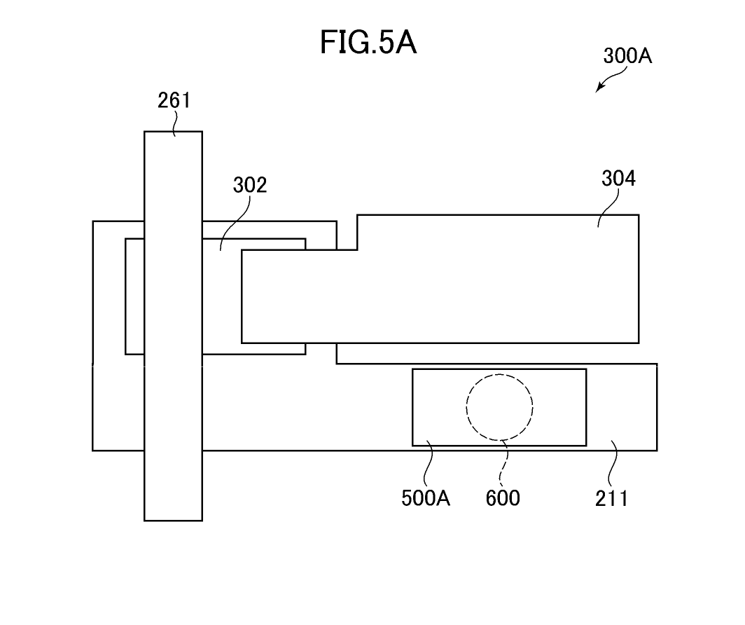

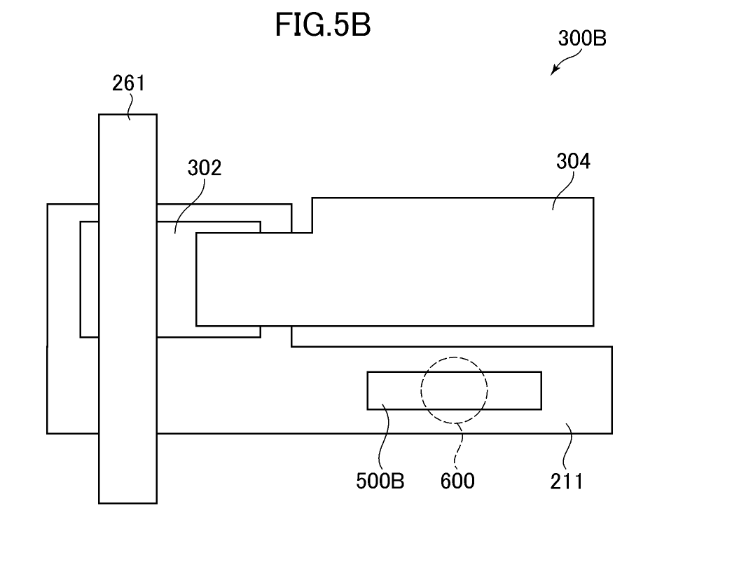

FIG. 5A illustrates a configuration of a TFT pattern 300A formed in the area A of the TFT substrate 220 according to a first embodiment. In the TFT pattern 300A illustrated in FIG. 5A, a seat 500A that receives a columnar spacer disposed on the color filter substrate 230 is formed on the gate line 211 which is the scanning signal line. For example, the seat 500A is formed so that an upper surface of the seat 500A has a size that covers 100% of an end surface 600 (contact surface) of the columnar spacer. In a process of forming the source electrode 304 which is the pixel electrode, the seat 500A can be formed in the same layer as that of the source electrode 304 with the same material as that of the source electrode 304.

FIG. 5B illustrates a configuration of a TFT pattern 300B formed in the area B of the TFT substrate 220 according to the first embodiment. In the TFT pattern 300B illustrated in FIG. 5B, a seat 500B that receives the columnar spacer disposed on the color filter substrate 230 is formed on the gate line 211 which is the scanning signal line. An area of an upper surface of the seat 500B is smaller than an area of the upper surface of the seat 500A. For example, the seat 500B is formed so that the upper surface of the seat 500B has a size that covers 50% of the end surface 600 (contact surface) of the columnar spacer. In the process of forming the source electrode 304 which is the pixel electrode, the seat 500B can be formed in the same layer as that of the source electrode 304 with the same material as that of the source electrode 304.

The TFT patterns 300 illustrated in FIG. 3 is formed in the area C of the TFT substrate 220. It is needless to say that the seat may be formed on the gate line 211 of the TFT patterns 300 formed in the area C. The area of the upper surface of the seat formed in this case is set to be smaller than the area of the upper surface of the seat 500B.

After a coloring layer (RGB film) and a transparent conductive film have been formed on the color filter substrate 230, a spacer material is coated on the color filter substrate 230 to form the columnar spacers through a given process. In this situation, the shapes (heights and widths) of the columnar spacers formed on the color filter substrate 230 can be identical with each other, and the distribution of the columnar spacers in a plane of the color filter substrate 230 can be also uniform.

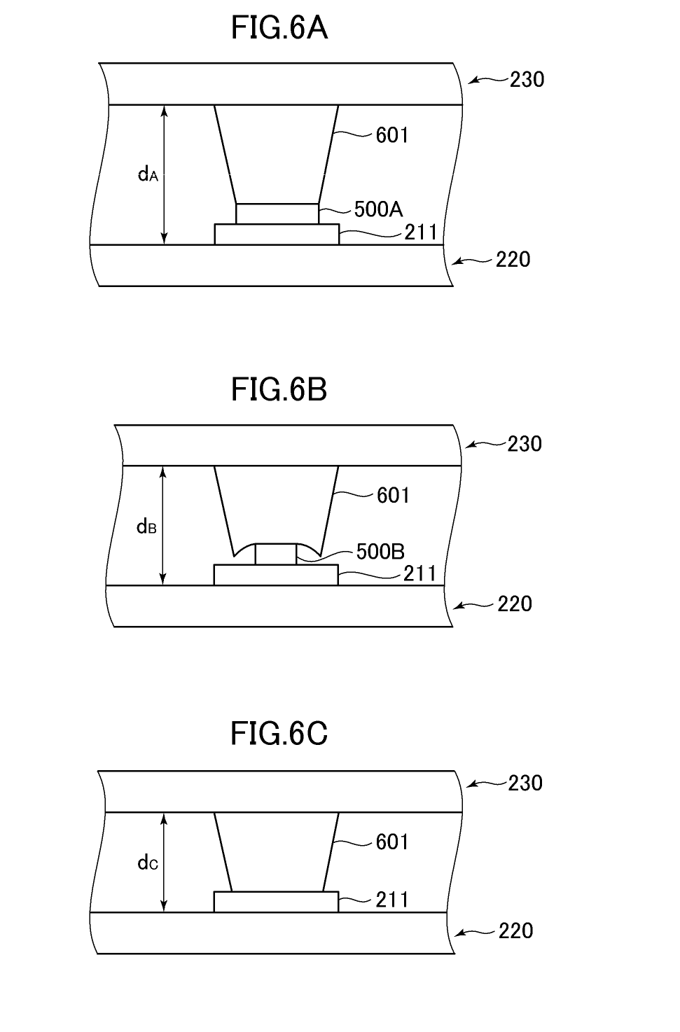

FIGS. 6A to 6C are diagrams illustrating a distance between the TFT substrate 220 and the color filter substrate 230 when the TFT substrate 220 and the color filter substrate 230 adhere to each other according to the first embodiment. FIG. 6A illustrates a contact state between the TFT pattern 300A and a facing columnar spacer 601 in the area A, FIG. 6B illustrates the contact state between the TFT pattern 300B and the facing columnar spacer 601 in the area B, and FIG. 6C illustrates the contact state between the TFT pattern 300 and the facing columnar spacer 601 in the area C.

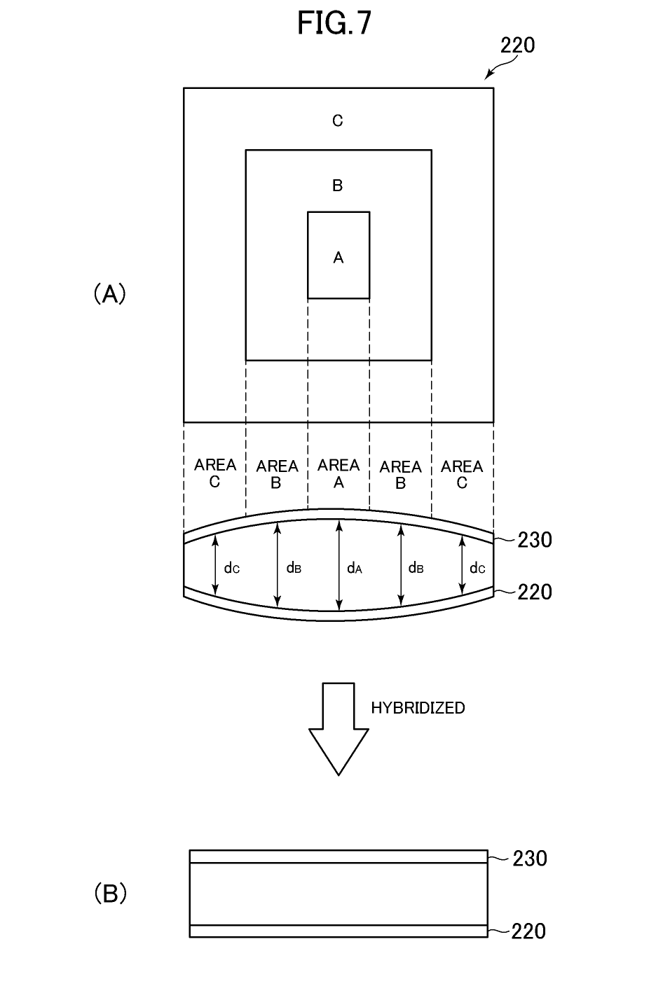

As illustrated in FIG. 6A, because an entire contact surface of the columnar spacer 601 in the area A is supported by the facing seat 500A, a drag caused by the columnar spacer 601 is larger than that of the columnar spacer 601 that contacts with the TFT pattern 300 in each of the areas B and C. Also, as illustrated in FIG. 6B, because a partial contact surface of the columnar spacer 601 in the area B is supported by the facing seat 500B, the drag caused by the columnar spacer 601 is smaller than that in the area A, but larger than that in the area C. For that reason, in the liquid crystal panel 200 in which the TFT substrate 220 and the color filter substrate 230 adhere to each other, and liquid crystal is sealed therebetween, there occurs a difference in a distance between those substrates in the areas A to C of the TFT substrate 220, and a relationship among those distances satisfies d_{A}>d_{B}>d_{C} as illustrated in FIG. 7-(A) before the liquid crystal panel and the front window are hybridized, assuming that the distance between those substrates in the area A is d_{A}, the distance between those substrates in the area B is d_{B}, and the distance between those substrates in the area C is d_{C}.

On the contrary, when the liquid crystal panel 200 and the upper frame 110 (front window) are hybridized (adhered with a UV resin), a larger stress is exerted on the center portion of the liquid crystal panel 200 than the outer portion thereof. As a result, although the distance between the TFT substrate 220 and the color filter substrate 230 is larger in the center portion and smaller in the peripheral portion before the liquid crystal panel and the front window are hybridized (refer to FIG. 7-(A)), the distance between those substrates is uniformed as a whole after the liquid crystal panel and the front window have been hybridized as illustrated in FIG. 7-(B).

In the liquid crystal panel 200 according to the first embodiment as described above, the area of the seat disposed on the gate line 211 which supports the columnar spacer 601 becomes smaller outward from the center portion in the TFT substrate 220. With this configuration, the distance between the TFT substrate 220 and the color filter substrate 230 can be made narrower outward from the center before the liquid crystal panel 200 and the front window are hybridized. As a result, after the liquid crystal panel and the front window have been hybridized, the distance between the TFT substrate 220 and the color filter substrate 230 are uniformed on the overall surface, and the color unevenness can be prevented from occurring in the peripheral portion of the liquid crystal panel 200. Also, the in-plane distribution of the surface areas of the seats provided on the gate lines 211 is changed. With this configuration, while the shapes and the in-plane distributions of the columnar spacer 601 are kept uniform, the distance between the TFT substrate 220 and the color filter substrate 230 can be made narrower outward from the center before the liquid crystal panel and the front window are hybridized.

### Second Embodiment

Subsequently, a description will be given of an example (second embodiment) in which the seat is formed below the pixel electrode.

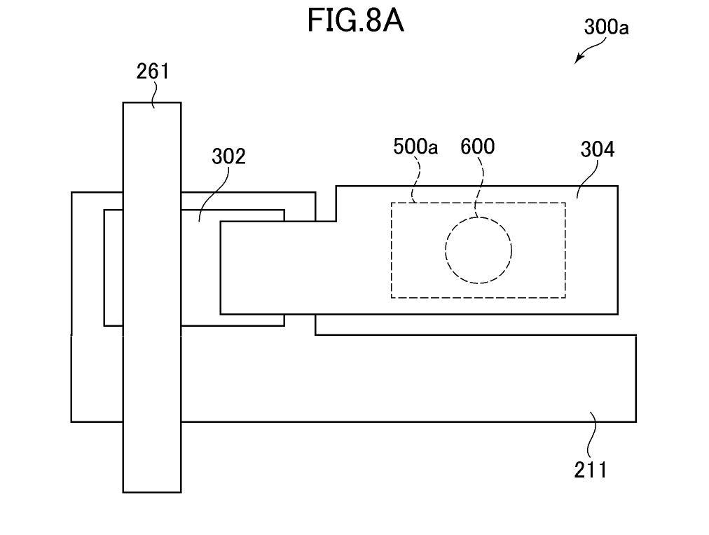

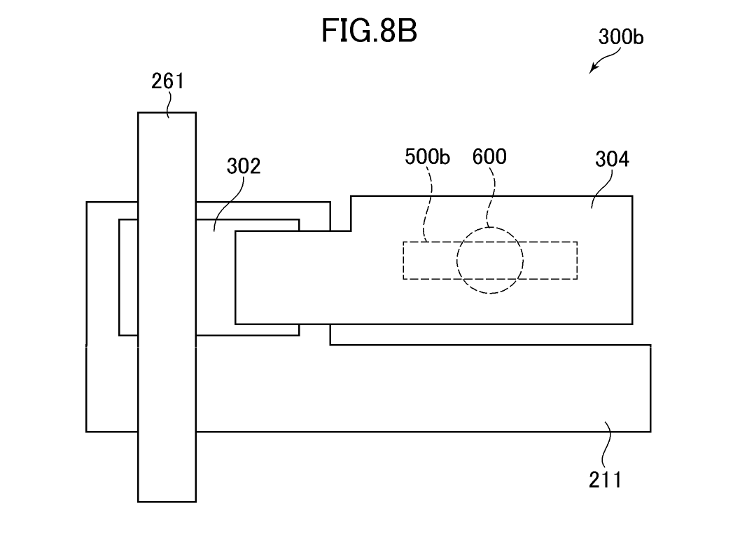

FIG. 8A illustrates a configuration of the TFT pattern 300A formed in the area A of the TFT substrate 220 according to a second embodiment. In a TFT pattern 300a illustrated in FIG. 8A, a seat 500a that receives the columnar spacer 601 disposed on the color filter substrate 230 is formed below the source electrode 304 (between the source electrode 304 and an insulating film disposed below the source electrode 304), which is the pixel electrode. For example, the seat 500a can be formed so that an upper surface of the seat 500a has a size that covers 100% of the end surface 600 (contact surface) of the columnar spacer. In a process of forming the gate line 211 which is the scanning signal line, the seat 500a can be formed in the same layer as that of the gate line 211 with the same material as that of the gate line 211.

FIG. 8B illustrates a configuration of a TFT pattern 300b formed in the area B of the TFT substrate 220 according to the second embodiment. In the TFT pattern 300b illustrated in FIG. 8B, a seat 500b that receives the columnar spacer disposed on the color filter substrate 230 is formed below the source electrode 304 (between the source electrode 304 and an insulating film below the source electrode 304) which is the pixel electrode. An area of an upper surface of the seat 500b is smaller than an area of the upper surface of the seat 500a. For example, the seat 500b can be formed so that the upper surface of the seat 500b has a size that covers 50% of the end surface 600 (contact surface) of the columnar spacer. In the process of forming the gate line 211 which is the scanning signal line, the seat 500b can be formed in the same layer as that of the gate line 211 with the same material as that of the gate line 211.

Similarly, in the second embodiment, the TFT pattern 300 illustrated in FIG. 3 can be formed in the area C of the TFT substrate 220. It is needless to say that the seat can be also formed on the gate line 211 of the TFT pattern 300 formed in the area C. The area of the upper surface of the seat formed in this case is set to be smaller than the area of the upper surface of the seat 500b.

As in the first embodiment, in the second embodiment, after a coloring layer (RGB film) and a transparent conductive film have been formed on the color filter substrate 230, a spacer material can be coated on the color filter substrate 230 to form the columnar spacers through a given process. In this situation, the shapes (heights and widths) of the columnar spacers formed on the color filter substrate 230 can be identical with each other, and the distribution of the columnar spacers in a plane of the color filter substrate 230 can be also uniform.

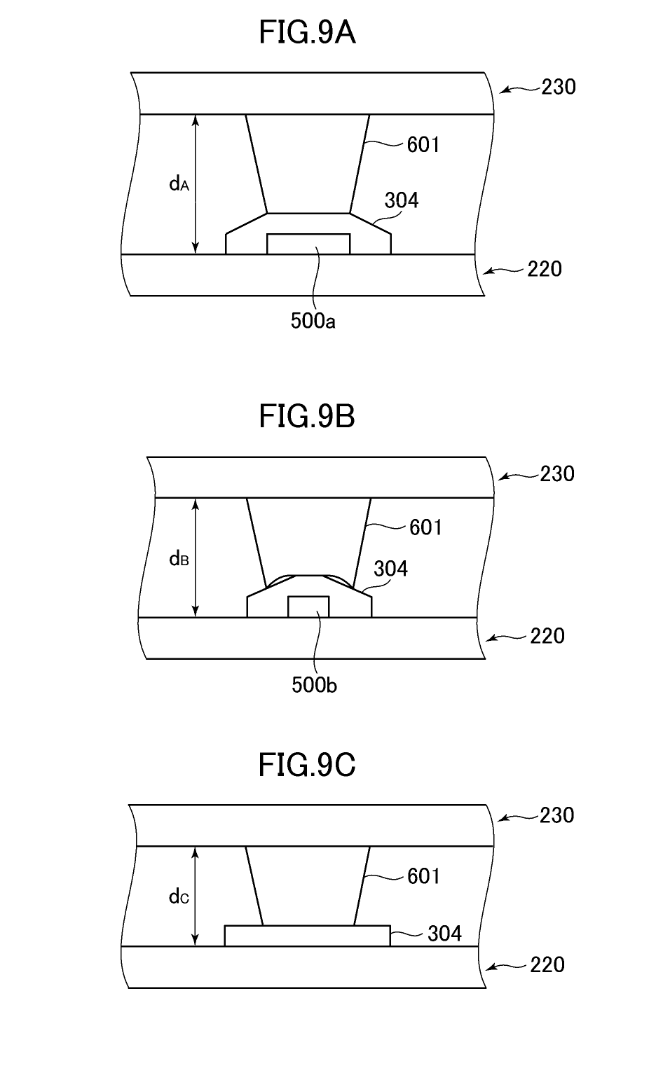

FIGS. 9A to 9C are diagrams illustrating a distance between the TFT substrate 220 and the color filter substrate 230 when the TFT substrate 220 and the color filter substrate 230 adhere to each other according to the second embodiment. FIG. 9A illustrates a contact state between the TFT pattern 300a and the facing columnar spacer 601 in the area A, FIG. 9B illustrates the contact state between the TFT pattern 300b and the facing columnar spacer 601 in the area B, and FIG. 9C illustrates the contact state between the TFT pattern 300 and the facing columnar spacer 601 in the area C.

As illustrated in FIG. 9A, because an entire contact surface of the columnar spacer 601 in the area A is supported by the source electrode 304 raised from the facing seat 500a, a drag caused by the columnar spacer 601 is larger than that of the columnar spacer 601 that contacts with the TFT pattern 300 in each of the areas B and C. Also, as illustrated in FIG. 9B, because a partial contact surface of the columnar spacer 601 in the area B is supported by the source electrode 304 raised from the facing seat 500b, the drag caused by the columnar spacer 601 is smaller than that in the area A, but larger than that in the area C. For that reason, in the liquid crystal panel 200 in which the TFT substrate 220 and the color filter substrate 230 adhere to each other, and liquid crystal is sealed therebetween, there occurs a difference in a distance between those substrates in the areas A to C of the TFT substrate 220, and a relationship among those distances satisfies d_{A}>d_{B}>d_{C} as illustrated in FIG. 7-(A) before the liquid crystal panel and the front window are hybridized, assuming that the distance between those substrates in the area A is d_{A}, the distance between those substrates in the area B is d_{B}, and the distance between those substrates in the area C is d_{C}.

On the contrary, when the liquid crystal panel 200 and the upper frame 110 (front window) are hybridized (adhered with a UV resin), a larger stress is exerted on the center portion of the liquid crystal panel 200 than the outer portion thereof . As a result, although the distance between the TFT substrate 220 and the color filter substrate 230 is larger in the center portion and smaller in the peripheral portion before the liquid crystal panel and the front window are hybridized (refer to FIG. 7-(A)), the distance between those substrates is uniformed as a whole after the liquid crystal panel and the front window have been hybridized as illustrated in FIG. 7-(B).

In the liquid crystal panel 200 according to the second embodiment as described above, the area of the seat disposed below the pixel electrode which supports the columnar spacer 601 through the pixel electrode becomes smaller outward from the center portion in the TFT substrate 220. With this configuration, the distance between the TFT substrate 220 and the color filter substrate 230 can be made narrower outward from the center before the liquid crystal panel 200 and the front window are hybridized. As a result, after the liquid crystal panel and the front window have been hybridized, the distance between the TFT substrate 220 and the color filter substrate 230 are uniformed on the overall surface, and the color unevenness can be prevented from occurring in the peripheral portion of the liquid crystal panel 200. Also, the in-plane distribution of the surface areas of the seats disposed below the pixel electrode is changed. With this configuration, while the shapes and the in-plane distributions of the columnar spacer 601 are kept uniform, the distance between the TFT substrate 220 and the color filter substrate 230 can be made narrower outward from the center before the liquid crystal panel and the front window are hybridized.

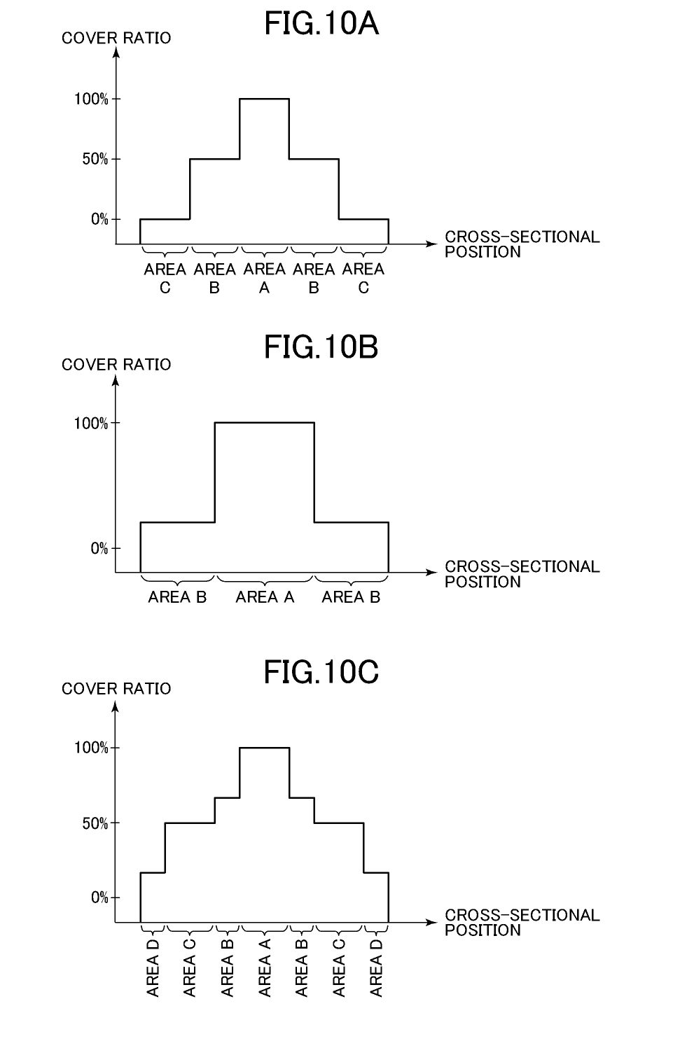

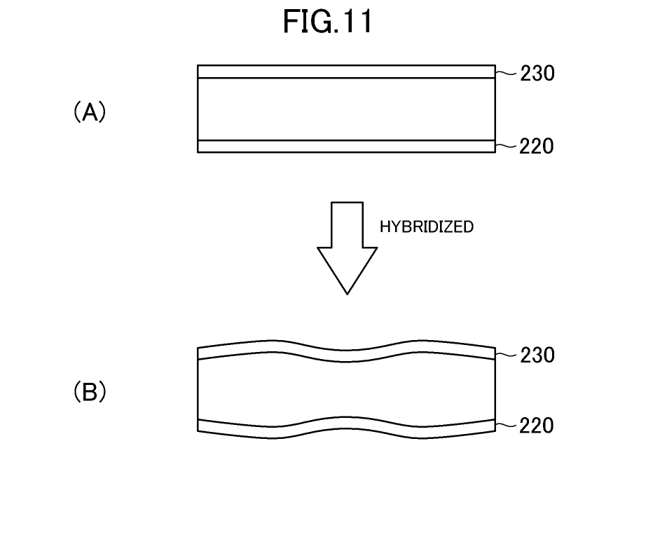

FIGS. 10A to 10C illustrate examples of a relationship between a position of the liquid crystal panel 200 in a cross-section, and a cover ratio of the end surface 600 of the columnar spacer by the seat.

FIG. 10A illustrates an example of the above-mentioned first and second embodiments. As illustrated in FIG. 10A, the cross-section of the liquid crystal panel 200 is divided into the area A of the center portion, the area B of the intermediate portion, and the area C of the peripheral portion. The contact area between the seat and the columnar spacer 601 is made smaller in the stated order of the area A, the area B, and the area C. In the above-mentioned first and second embodiments, no seat is provided in the area C. However, the seat can be provided in the area C.

It is needless to say that the present invention is not limited to the above embodiments. For example, as illustrated in FIG. 10B, the area extending from the center portion of the TFT substrate 220 to the peripheral portion thereof is divided into the area A of the center portion, and the area B outside of the area A, and the contact area between the seat and the columnar spacer 601 can be made smaller in the stated order of the area A and the area B. Also, as illustrated in FIG. 10C, the area expanding from the center portion of the TFT substrate 220 to the peripheral portion can be divided into the area A of the center portion, the area B outside of the area A, the area C outside of the area B, and an area D of an outermost portion. The contact area between the seat and the columnar spacer 601 can be made smaller in the stated order of the area A, the area B, the area C, and the area D. It is needless to say that the number of areas is not limited to the above-mentioned examples, and the other number of areas can be applied.

Also, in the above embodiment, the seat is shaped into a rectangular solid, but other shapes such as a cone may be applied.

When the UV resin is coated on the entire surface of a portion where the liquid crystal panel 200 and the front window adhere to each other for adhesion, the yellow border is liable to occur. In this case, the effect of suppressing the occurrence of the yellow border becomes more remarkable by applying the present invention.

While there have been described what are at present considered to be certain embodiments of the invention, it will be understood that various modifications may be made thereto, and it is intended that the appended claim cover all such modifications as fall within the true spirit and scope of the invention.

What is claimed is:

1. A liquid crystal display device comprising:
a TFT substrate on which a plurality of TFT patterns each having a scanning signal line, a data signal line, and a pixel electrode are formed;
a color filter substrate which is arranged to face the TFT substrate; and
a plurality of columnar spacers which are formed on a surface of the color filter substrate facing the TFT substrate,
wherein at least a part of the plurality of TFT patterns includes a seat that is formed over the scanning signal line or below the pixel electrode, and directly or indirectly supports one of the plurality of columnar spacers, and
wherein an area in which the seat provided in the TFT pattern formed in a center portion of the TFT substrate supports the columnar spacer is larger than an area in which the seat provided in the TFT pattern formed outside of the center portion of the TFT substrate supports the columnar spacer.

2. The liquid crystal display device according to claim 1,
wherein the area in which the seat provided in the TFT pattern formed in the TFT substrate supports the columnar spacer becomes smaller outward from the center portion of the TFT substrate.

3. The liquid crystal display device according to claim 2,
wherein the seat provided in the TFT pattern formed in the center portion of the TFT substrate supports an entire end surface of the columnar spacer,
wherein the seat provided in the TFT pattern formed between the center portion and a peripheral portion of the TFT substrate supports a partial end surface of the columnar spacer, and
wherein no seat is provided in the TFT pattern formed in the peripheral portion of the TFT substrate.

4. The liquid crystal display device according to claim 1,
wherein when the seat is formed over the scanning signal line, the seat is made of the same material as that of the pixel electrode, and formed in the same layer as that of the pixel electrode, and
wherein when the seat is formed below the pixel electrode, the seat is made of the same material as that of the scanning signal line, and formed in the same layer as that of the scanning signal line.

5. The liquid crystal display device according to claim 1,
wherein heights of the seats provided in the plurality of TFT patterns are identical with each other.

6. The liquid crystal display device according to claim 1,
wherein the plurality of columnar spacers has the same shape, and
wherein the plurality of columnar spacers are arranged on the color film substrate at predetermined intervals.
